(19) United States
(12) Patent Application Publication
(10) Pub. No.: US 2010/0244180 A1
(43) Pub. Date: Sep. 30, 2010

(54) METHOD FOR FABRICATING DEVICE ISOLATION STRUCTURE

(75) Inventors: Yung-Tai Hung, Hsinchu (TW); Chin-Ta Su, Hsinchu (TW); Ta-Hung Yang, Hsinchu (TW)

Correspondence Address: J C PATENTS, 4 VENTURE, SUITE 250, IRVINE, CA, 92618, US

(73) Assignee: MACRONIX INTERNATIONAL CO., LTD., Hsinchu (TW)

(21) Appl. No.: 12/411,189

(22) Filed: Mar. 25, 2009

(51) Int. Cl. H01L 29/06; H01L 21/762; H01L 21/311

(52) U.S. Cl. 257/506; 438/424; 257/E29.02; 257/E21.546; 257/E21.257

(57) ABSTRACT

A method of a fabricating a semiconductor device includes providing a substrate having a first region and a second region. A pad layer is formed overlying the substrate in both the first region and the second region. A mask layer is then formed overlying the pad layer. Thereafter, the mask layer, the pad layer and the substrate are patterned to form a plurality of first trenches in the first region and a plurality of second trenches in the second region. A trimming process is then performed on the mask layer to remove a portion of the mask layer. An insulation layer is formed over the substrate and fills the plurality of the first trenches and the plurality of the second trenches. Ultimately, a planarization process is performed on the insulation layer.

### BACKGROUND OF THE INVENTION

1. Field of Invention

The present invention relates to a method for fabricating a semiconductor device. More particularly, the present invention relates to a method for fabricating a device isolation structure.

2. Description of Related Art

A semiconductor device is composed of many devices and isolation structures that isolate the devices. The isolation structures, such as, shallow trench isolation (STI) structures, are used to prevent carriers from moving between devices, for example, memory devices.

FIG. 1 is cross-sectional view of a portion of a semiconductor device having device isolation structures. Conventionally, the device isolations structures are formed by forming an oxide layer overlying a substrate. A nitride layer is formed overlying the oxide layer. The nitride, the oxide layer and the substrate are then patterned to form a plurality of trenches in the substrate. Thereafter, a dielectric material is formed over the substrate such that the plurality of the trenches is filled with the dielectric material. Ultimately, the excess dielectric layer outside the trenches is removed, and the nitride layer and the underlying oxide layer are also removed. As shown in FIG. 1, due to the differences in pattern density, the dielectric material is removed in different rates between the regions with a higher trench density 102 and the regions with a lower trench density 104. Normally, dishing of the upper surface of the trenches occurs in the regions having a lower trench density.

### SUMMARY OF THE INVENTION

The present invention is to provide a method of fabricating a semiconductor device having device isolations structures, wherein the step height of the trench isolation structures in the high trench density region is lower than that of the trench isolation structures in the low trench density region.

The present invention is to provide a method of fabricating a semiconductor device having device isolations structures, and the method includes providing a substrate having a first region and a second region. A plurality of first trenches is formed in the first region and a plurality of second trenches is formed in the second region. An insulation layer is then formed over the substrate filling the first trenches and the second trenches. Ultimately, a planarization process is performed on the insulation layer to create a first step height in the first trenches and a second step height in the second trenches.

In accordance to an aspect of the invention, the method of fabricating a semiconductor device having device isolations structures may include forming a mask layer over the substrate. Thereafter, the mask layer, and the substrate are patterned to form the plurality of first trenches in the first region and the plurality of second trenches in the second region. A trimming process is then performed on the mask layer to remove a portion of the mask layer to form a trimmed mask layer in the first region. After this, the insulation layer is formed over the substrate and fills the plurality of the first trenches and the plurality of the second trenches. The planarization process is further performed on the insulation layer.

In accordance to an aspect of the invention, the trench density of the first region is higher than that in the second region.

According to an aspect of the invention, the first region includes an array region, while the second region includes a periphery region.

According to an aspect of the invention, the trimming process and the formation of the insulation layer are conducted concurrently.

According to an aspect of the invention, the trimming process is performed in-situ when the insulation layer is being deposited in a high density plasma chemical vapor deposition (HDPCVD) process.

According to an aspect of the invention, the HDPCVD process includes a first stage process and a second stage process, wherein the etching/deposition (E/D) ratio of the first stage process is higher than the E/D ratio of the second stage process.

According to an aspect of the invention, the E/D ratio of the first stage process is about 0.05˜0.4, while the E/D ratio of the second stage process is about 0.05˜0.25.

According to an aspect of the invention, the bias power of the low frequency radio frequency of the first stage process of the HDPCVD process is about 1000˜4000 W, and the bias power of the high frequency radio frequency of the first stage process of the HDPCVD process is about 1000˜4000 W.

According to an aspect of the invention, the bias power of the low frequency radio frequency of the second stage process of the HDPCVD process is about 1000˜4000 W, and the bias power of the high frequency radio frequency of the second stage process of the HDPCVD process is about 1000˜4000 W.

According to an aspect of the invention, the trimmed mask layer has a substantially triangular, hexagonal or trapezoidal cross-section.

According to an aspect of the invention, the trimming process is performed to remove the upper edges of two opposite sides of the mask layer in the first region.

According to an aspect of the invention, the trimming process includes an etching process.

According to an aspect of the invention, the trimmed mask layer has a bullet-like cross-section.

According to an aspect of the invention, the trimming process includes a dry etch process.

According to an aspect of the invention, the etch gas used in the dry etch process includes at least one of CF₄, CHF₃, CH₂F₂, Ar, SF₆, O₂, HBr, Cl₂ and H₂O₂.

According to an aspect of the invention, the dry etch process is performed with a source power of about 100 to 1000 W, for example, and a bias power of about 30 to 1000 W, for example.

According to an aspect of the invention, the trimming process includes a wet etch process.

According to an aspect of the invention, an etchant used in the wet etch process includes, but not limited to, H₃PO₄ (86%). According to an aspect of the invention, the wet etch process is performed, for example, under a temperature between about 50° C. to 200° C., for example, for about 5 to 120 minutes, for example.

According to an aspect of the invention, the trimming process includes reducing the thickness, the width and the length of the mask layer. According to an aspect of the invention, the trimming process includes an in-situ steam generation process.

According to an aspect of the invention, the first step height ranges from −500 to 0 angstrom from the surface of the substrate. According to an aspect of the invention, the second step height ranges from −400 to 300 angstrom from a surface of the substrate.

The present invention also provides a semiconductor device having at least a first region and a second region that include respectively a plurality of first trench isolation structures and a plurality of second trench isolation structures configured in a substrate, wherein the trench density is higher in the first region than in the second region, and the step height of the plurality of the first trench isolation structures is higher than the step height of the plurality of the second trench isolation structures.

In accordance to the semiconductor device of the present invention, the surface of the trench isolation structure is about 450 Å to 550 Å, and is preferably about 0˜500 Å below the surface of the substrate.

In accordance to the semiconductor device of the present invention, the surface of the first region is protruded above the surface of the substrate.

In accordance to the semiconductor device of the present invention, wherein the first region is an array region and the second region is a periphery region of a flash memory device.

In accordance to the semiconductor device of the present invention, the erase saturation (electron current from the gate to the charge trapping layer across top-dielectric) of the flash memory device is improved due to the improvement of the electric field at the STI edge.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a cross-sectional view of a portion of a substrate, schematically illustrating conventional STI structures.

FIGS. 2A-2F are cross-sectional views of a portion of a substrate, schematically illustrating a method of fabricating shallow trench isolation (STI) structures according to one aspect of the invention.

FIG. 3 is a cross-sectional view of a portion a substrate, schematically illustrating the trimmed mask layer according another aspect of the invention.

FIG. 4 is a cross-sectional view of a portion a substrate, schematically illustrating the trimmed mask layer according another aspect of the invention.

FIG. 5 is a cross-sectional view of a portion a substrate, schematically illustrating the trimmed mask layer according another aspect of the invention.

FIG. 6 is a cross-sectional view of a portion a substrate, schematically illustrating the trimmed mask layer according another aspect of the invention.

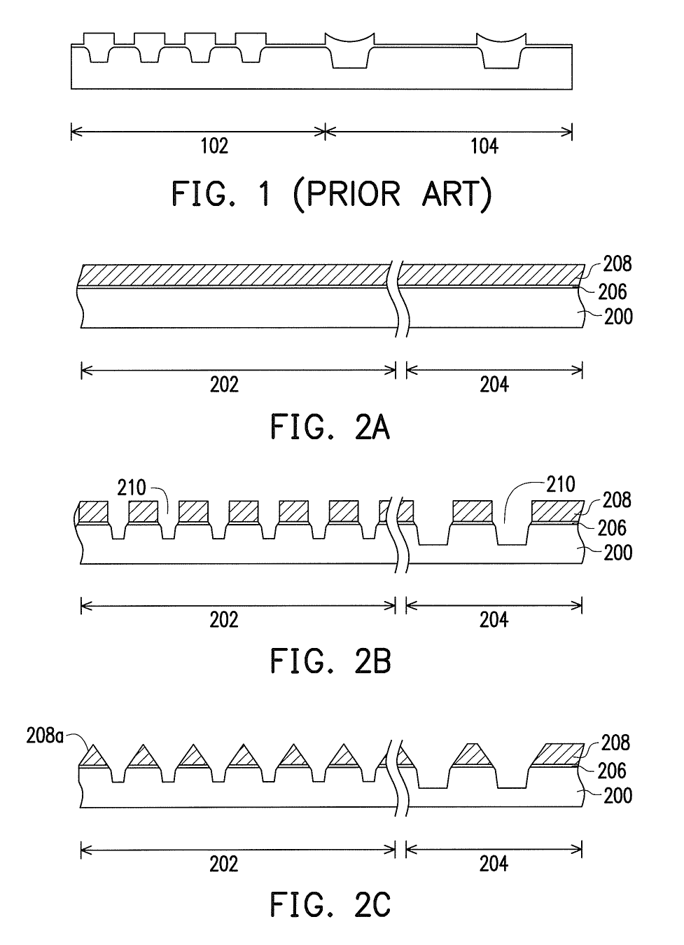

### DESCRIPTION OF EMBODIMENTS

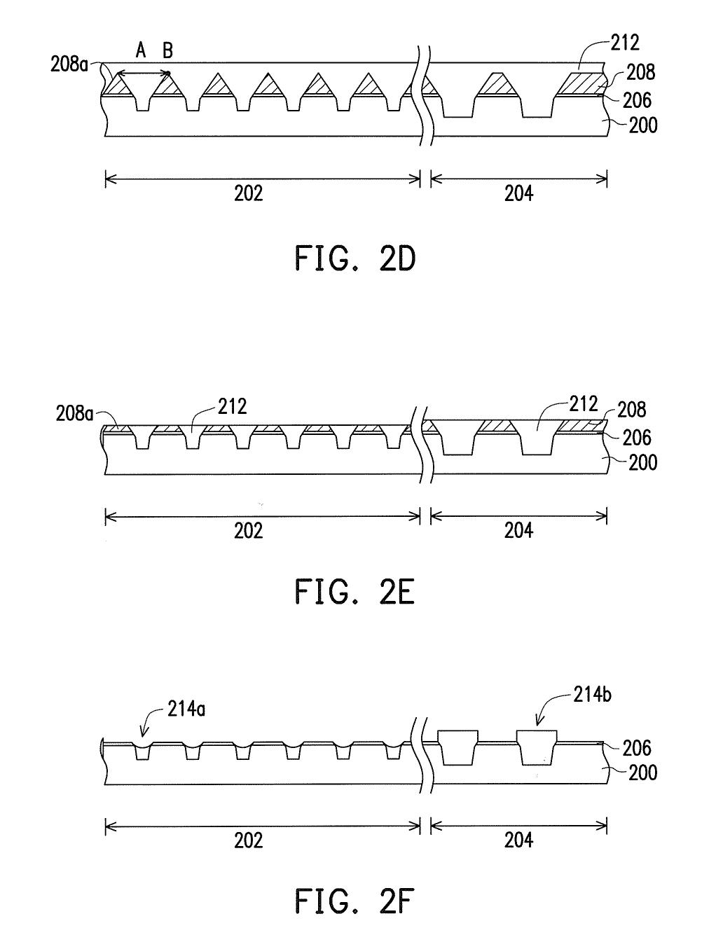

Reference will now be made in detail to the embodiments of the invention, examples of which are illustrated in the accompanying drawings. Whenever possible, the same reference numbers are used in the FIGS. 2A-2F, 3-5 of the drawings and the description to refer to the same or like parts.

FIGS. 2A-2F are schematic cross-sectional views of a portion of a substrate, illustrating a method of fabricating shallow trench isolation (STI) structures according to one aspect of the invention.

Referring to FIG. 2A, a semiconductor substrate 200 is provided. The semiconductor substrate 200 may be a silicon, a silicon on insulator, an epitaxial silicon substrate, for example. Further, the substrate 200 includes at least a first region 202 and a second region 204. The first region 202 is an array region and the second region 204 is a peripheral region, for example. The method of the invention also includes forming a dielectric layer overlying the first region 202 and the second region 204. The dielectric layer is, for example, a pad layer 206 formed by growing an oxide material on the top surface of semiconductor substrate 200. The pad layer 206 is about 100 to 120 angstroms thick, for example.

A mask layer 208 is constructed overlying the pad layer 206. In an aspect of the invention, the mask layer 208 is a silicon nitride layer, formed by, for example, chemical vapor deposition with a thickness of about 700 Å to about 1400 Å.

Referring to FIG. 2B, a portion of the mask layer 208, the pad layer 206 and the substrate 200 are removed to form a plurality of trenches 210 in the substrate 200 in both the first region 202 and the second region 204. The trenches 210 are formed, for example, by providing a patterned photoresist layer (not shown) over the mask layer 208 and performing an anisotropic etching using the patterned photoresist layer as a mask. In one aspect of the invention, a liner layer (not shown) may form on the surface of the trenches 210. The method of forming the liner layer includes, for example but not limited to, a thermal oxidation process. In this aspect of the invention, the first region 202 has a higher trench density than the second region 204.

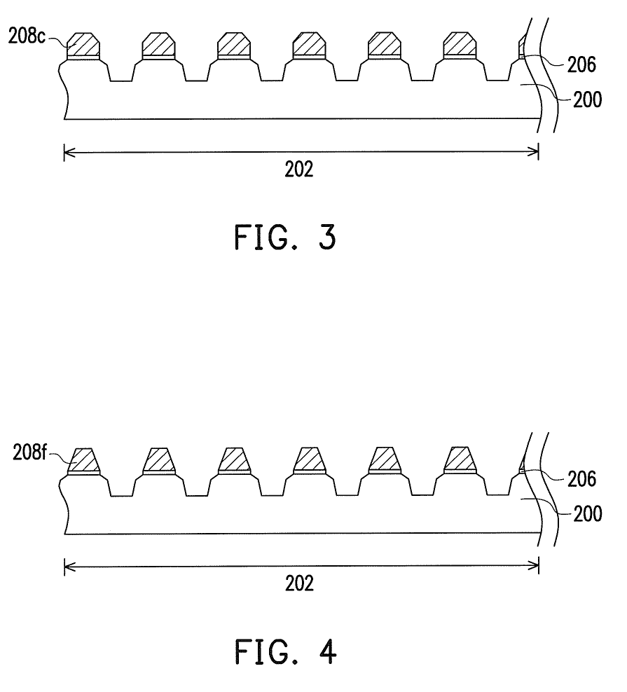

Referring to FIG. 2C, a trimming process is performed to remove a portion of the mask layer 208 such that the area of the top surface of the mask layer 208 is reduced. In one aspect of the invention, after the trimming process, the mask layer 208a in the first region 202 has a triangular shape. In another aspect of the invention, the trimming process is conducted to trim just the upper edges of two opposite sides of the mask layer 208 in the first region 202 to form a mask layer 208c with a substantially hexagonal cross-section as shown in FIG. 3. In yet another aspect of the invention, the trimming process is conducted to trim the two opposite sides of the mask layer 208, in a gradient from the top surface of the mask 208 layer to the bottom surface of the mask layer 208, in the first region to form a mask layer 208f with a substantially trapezoidal cross-section as shown in FIG. 4. Due to the differences in the pattern density, the mask layer 208 in the second region 204 is moderately trimmed. Continuing to FIG. 2D, an insulation layer 212 is formed to cover the mask layer 208a, 208 and to completely fill the trenches 210. The insulation layer 212 can be, for example, a silicon oxide layer.

In one particular aspect of the invention, a high-density plasma chemical vapor deposition (HDPCVD) process is performed to concurrently form the triangular-shaped mask layer 208a and depositing the insulation layer 212. It is noted that the high density plasma chemical vapor deposition (HDPCVD) process can provide the effect of deposition and etching by properly controlling process parameters, such as the bias power of radio frequency. In this aspect of the invention, the HDPCVD process includes at least a first stage process and a second stage process, wherein the first stage process and the second stage process have different etching/deposition (E/D) ratios. The first stage process of the high density plasma chemical vapor deposition (HDPCVD) process having a higher etching/deposition (E/D) ratio is performed to remove a portion of the mask layer 208, while the insulation layer 212 is also being deposited. In the first stage process of the high density plasma chemical vapor deposition process, the etching to deposition (E/D) ratio is, for example, between 0.05 to 0.4. In one aspect of the invention, the etching to deposition (E/D) ratio is between about 0.1 to about 0.4. In another aspect of the invention, the etching to deposition (E/D) ratio is between about 0.15 to about 0.4, for example. The bias power of the low frequency radio frequency (LF) of the first stage process of the HDPCVD process is, for example, between 1000 to 4000 W, possibly between about 2000 to about 4000 W, and also possibly between about 2500 to about 4000 W. The bias power of the high frequency radio frequency of the HDPCVD process is, for example, between about 1000 to 4000 W, possibly between about 2000 to about 4000 W, and also possibly between about 2500 to about 4000 W. The gaseous mixture required for the HDPCVD is produced by passing at least silane SiH₄ and oxygen, wherein the flow rate of silane SiH₄ is between about 50 sccm and 450 sccm, for example, while the flow rate of oxygen is between about 50 sccm and 450 sccm.

The second stage process of the high density plasma chemical vapor deposition process continues after the first stage process, wherein the E/D ratio of the second stage process is adjusted to 0.05 to 0.25. In another aspect of the invention, the E/D ratio of the second stage process is between about 0.1 to about 0.25, for example. The bias power of the low frequency radio frequency (LF) of the second stage process of the HDPCVD process is, for example, between about 1000 to about 4000 W, and also possibly between about 1500 to about 4000 W. The bias power of the high frequency radio frequency of the second stage process of the HDPCVD process is, for example, between about 1000 to about 4000 W, and possibly between about 1500 to about 4000 W. During the second stage process, the flow rate of silane SiH₄ is between about 50 sccm and 450 sccm, for example, while the flow rate of oxygen is between about 50 sccm and 450 sccm.

Thereafter, as shown in FIG. 2E, a planarization process is performed to planarize the insulation layer 212. The planarization process includes, for example, a chemical mechanical polishing (CMP) process. The planarization process continues until the top portion of the mask layer 208a in the first region 202 has been polished off. Ultimately, the remaining of the mask layer 208a, 208 is removed as shown in FIG. 2F, and STI structures 214a, 214b are respectively formed in the first region 202 and the second region 204. The removing method includes, for example, using a hot phosphoric acid as an etchant to perform a wet etching process.

Since the mask layer 208a in the array region 202 is trimmed to have a triangular cross-section, the ratio of the area of the insulation layer 212 (designated as “A” in FIG. 2D) to that of the mask layer 208a (designated as “B” in FIG. 2D) increases. Hence, subsequent to the planarization process and the removal of the mask layer 208a, dishing of the upper surface of the STI structures 214a is resulted in the first region 202 with a step height of about −500 to 0 angstrom measuring from the top surface of the substrate 100, for example, while protrusion of the STI structures 214b occurs in the second region 204 with a step height of about −400 angstrom to about 300 angstrom measuring from the top surface of the substrate 100, for example. In this embodiment of the invention, the top surface of the substrate is assumed to be a reference point and the step height of an isolation structure is defined as a distance from a top surface of the isolation structure to a top surface of the substrate, wherein the step height below the surface of the substrate is denoted as a negative step height, while the step height above the top surface of the substrate is denoted as a positive substrate. In one aspect of the invention, the STI structures 214a in the first region 202 have a step height of about −250 angstrom to about 0 angstrom.

Although in the above exemplary embodiment, the trimming of the mask layer 208 and the deposition of the insulation layer 212 are performed concurrently, it is well in the scope of the invention that the formation of the trimmed mask layer 208a is completed prior to the deposition of the insulation layer 212.

In another aspect of the invention, the trimming process is accomplished by performing an etching process. The etching process could be a dry etch process, in which the etching gas used includes, but not limited to, CF₄, CHF₃, CH₂F₂, Ar, SF₆, O₂, HBr, Cl₂, H₂O₂. Further, the source power of the dry etch process is between, for example, about 100 to 1000 W, possibly between 300 to 700 W, and also possibly between about 500 to 700 W; while the bias power of the dry etch process is between, for example, about 30 to 1000 W, possibly between about 50 to 500 W, and also possibly between about 200 to 500 W. In another aspect of the invention, the etching process could be a wet etch process. The etchant used in the wet etch process includes, but not limited to, H₃PO₄ (86%). The wet etch process is performed, for example, under a temperature between about 50° C. to 200° C., possibly between about 100° C. to 200° C., and also possibly between about 150° C. to 170° C. Further, the wet etch process is performed for about 5 to 120 minutes, and possibly for about 15 to 60 minutes, and also possibly for about 20 to 30 minutes. In another aspect of the invention, the etching process for trimming the upper edges of two opposite sides of the mask layer 208 includes a combination of a dry etch process and a wet etch process. In accordance to the present invention, the numbers and the sequence of the dry etch process and the wet etch process may vary depending on the process requirement.

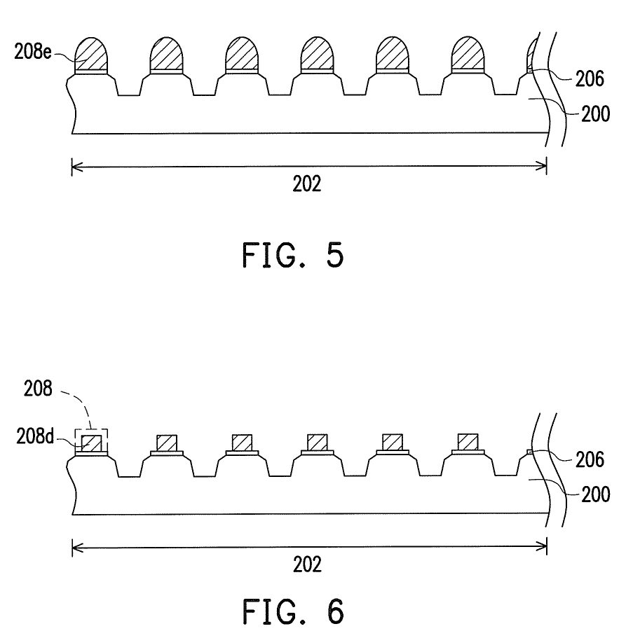

In one aspect of the invention, the resulting mask layer 208e, is trimmed to have a (bullet)like cross-section after the etching process, as shown in FIG. 5 with the upper surface area being reduced and smaller than the bottom surface area. Similar to the above aspect of the invention, the ratio of the area of isolation layer 212 to that of the mask layer 208c increases. Consequently, dishing of the upper surface of the STI structures 214a in the array region 202 is resulted subsequent to the planarization process, and protrusion of the STI structures 214b occurs in the periphery region 204. In yet another aspect of the invention, the trimming process is performed to trim the length, the width and the height of the mask layer 208 as shown in FIG. 6. The reduction of the critical dimension of the mask layer 208 in this aspect of the invention may be accomplished by performing an in-situ steam generation process (ISSG). In one example, the ISSG process is conducted with a gas ratio percentage of H₂/O₂ being about 1 to 33%, and possibly about 20 to 33%, and also possibly about 30 to 33%. Further, a flow rate of H₂ is about 0.1 to 30 slm, for example; a flow rate of O₂ is about 0.1 to 30 slm, for example; and a pressure of about 8.5 to 12 torr. Since the width of the resulting mask layer 208d is reduced as shown in FIG. 6, the ratio of the area of the isolation layer 212 to that of the mask layer 208d increases. Consequently, dishing of the upper surface of the STI structures 214a in the array region 202 is resulted subsequent to the planarization process, and protrusion of the STI structures 214b occurs in the periphery region 204.

In the above aspects of the invention, only the first region 202, for example, the array region is shown in FIGS. 3, 4, 5, 6; the second region 204, for example, the peripheral regions, is not illustrated. However, the ultimate profile of the STI structures 214b in the second region 204 of FIGS. 3, 4, 5, 6 is the same as STI structures 214b illustrated in FIG. 2F.

In accordance to the above disclosures, STI structures 214a, 214b are respectively configured in the first region 202 and the second region 204 of a semiconductor device, wherein the trench density in the first region 202 is higher than that in the second region 204. Moreover, the step height of the STI structures 214a in the first region 202 is lower than the step height of the STI structures 214b in the second region 200. In other words, due to the dishing of the upper surface of the STI structures 214a in the first region 202 and the protrusion of the STI structures above the surface of the substrate 200 in the second region 204, the thickness of the insulation layer 212 of the STI structures 214a in the first region 202 is less than the thickness of the insulation layer 212 of the STI structures 214b in the second region 204.

The STI structures of the invention are applicable many semiconductor devices. For example, in a flash memory device, such as a NAND device, a thinner STI structure 214a in the array region 202 improves the erase saturation of the flash memory device. Further, no additional photolithography or etching cost is mandated for the fabrication of the STI structures of the invention.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of fabricating a semiconductor device comprising a device isolation structure, the method comprising:
providing a substrate having a first region and a second region;
forming a pad layer over the substrate;
forming a mask layer over the pad layer;
patterning the mask layer, the pad layer and the substrate to form a plurality of first trenches in the first region and a plurality of second trenches in the second region;
performing a trimming process to remove at least a portion of an upper part of the mask layer to form a trimmed mask layer;
forming an insulation layer over the substrate and completely filling the plurality of the first trenches and the plurality of the second trenches; and
performing a planarization process on the insulation layer to form a plurality of first isolation structures and a plurality of second isolation structures in the first region and the second region respectively, wherein a top surface of each first isolation structure of the plurality of the first isolation structures is lower than a top surface of each second isolation structure of the plurality of the second isolation structures.

2. The method of claim 1, wherein the step of the trimming process and the step of forming the insulation layer are conducted concurrently by performing a high density plasma chemical vapor deposition (HDPCVD) process.

3. The method of claim 2, wherein the high density plasma chemical deposition process comprises a first stage process and a second stage process.

4. The method of claim 1, wherein the trimmed mask layer has a substantially triangular, trapezoidal or hexagonal cross-section in the first region.

5. The method of claim 1, wherein the trimming process is performed to remove upper edges of two opposite sides of the mask layer in the first region.

6. The method of claim 1, wherein the step of the trimming process comprises performing an etching process.

7. The method of claim 6, wherein the etching process includes a dry etch process.

8. The method of claim 7, wherein the dry etch process is conducted with an etch gas comprising at least one of CF₄, CHF₃, CH₂F₂, Ar, SF₆, O₂, HBr, Cl₂ and H₂O₂.

9. The method of claim 6, wherein the etching process includes a wet etch process.

10. The method of claim 1, wherein the step of the trimming process comprises reducing a thickness, a width and a length of the mask layer.

11. The method of claim 1, wherein the step of the trimming process comprises performing an in-situ steam generation process.

12. The method of claim 11, wherein the in-situ steam generation process is conducted with a ratio percentage of H₂/O₂ of about 1 to 33%, a H₂ flow rate of about 0.1 to 30 slm, an O₂ flow rate of about 0.1 to 30 slm, and a pressure of about 8.5 to 12 torrs.

13. The method of claim 1, wherein the first region is an array region, and the second region is a periphery region of the semiconductor device.

14. The method of claim 1, wherein the mask layer is removed after the planarization process is performed on the insulation layer.

15. The method of claim 1, wherein the plurality of first isolation structures has a first step height ranges from 500 to 0 angstrom below a top surface of the substrate and the plurality of second isolation structures has a second step height ranges from 400 below a top surface of the substrate to about 300 angstroms above the top surface of the substrate.

16. A semiconductor device comprising a first region and a second region that respectively comprises a plurality of first trench isolation structures and a plurality of second trench isolation structures configured in a substrate, wherein a trench density of the first region is higher than that of the second region, and a step height of the first trench isolation structures is lower than a step height of the second shallow trench isolation structures.

17. The semiconductor device of claim 16, wherein the first region comprises an array region, and the second region comprises a peripheral region.

18. The semiconductor device of claim 16, wherein a surface of the first shallow trench isolation structures is about 0 to 500 Å below a surface of the substrate.

19. The semiconductor device of claim 16, wherein a surface of the first shallow trench isolation structures is about 0 to 250 Å below a surface of the substrate.

20. The semiconductor device of claim 16, wherein a surface of the second shallow trench isolation structure is protruded above a surface of the substrate.

21. A method of fabricating a semiconductor device comprising a device isolation structure, the method comprising:
providing a substrate having a first region and a second region;
forming a plurality of first trenches in the first region and a plurality of second trenches in the second region wherein a trench density of the first region is higher than that of the second region;
forming an insulation layer over the substrate and filling the plurality of the first trenches and the plurality of the second trenches;
performing a planarization process on the insulation layer; and
creating a first step height in the first trenches and a second step height in the second trenches, wherein the first step height is lower than the second step height.

22. The method of claim 21, wherein the first step height ranges from 500 to 0 angstrom below a top surface of the substrate.

23. The method of claim 21, wherein the second step height ranges from 400 below a top surface of the substrate to about 300 angstroms above the top surface of the substrate.
